(19) United States
(12) Patent Application Publication
(10) Pub. No.: US 2019/0191596 A1
(43) Pub. Date: Jun. 20, 2019

(54) ELECTRICAL APPARATUS

(71) Applicant: TOYOTA JIDOSHA KABUSHIKI KAISHA, Toyota-shi (JP)

(72) Inventors: Yoshihiro MORITA, Okazaki-shi (JP); Jun ASADA, Toyota-shi (JP)

(73) Assignee: TOYOTA JIDOSHA KABUSHIKI KAISHA, Toyota-shi (JP)

(21) Appl. No.: 16/161,300

(22) Filed: Oct. 16, 2018

(30) Foreign Application Priority Data
Dec. 18, 2017 (JP) 2017-242147

(51) Int. Cl. H05K 7/20; H01L 23/473; F16L 5/12

(52) U.S. Cl. CPC H05K 7/20872; H01L 23/473; F25B 41/003; F16L 5/12; H05K 7/20927

(57) ABSTRACT

An electrical apparatus configured to be mounted in a vehicle includes a case that accommodates an electrical component; a cooler accommodated in the case and configured to cool the electrical component with use of a liquid refrigerant; and a refrigerant pipe that extends through a wall of the case and is connected to the cooler. A notch is provided on an outer surface of the refrigerant pipe such that the notch is located outside the case.

### INCORPORATION BY REFERENCE

The disclosure of Japanese Patent Application No. 2017-242147 filed on Dec. 18, 2017 including the specification, drawings and abstract is incorporated herein by reference in its entirety.

### BACKGROUND

### 1. Technical Field

The disclosure relates to an electrical apparatus configured to be mounted in a vehicle.

### 2. Description of Related Art

A control unit (electrical apparatus) that is mounted in a vehicle is described in Japanese Patent Application Publication No. 2012-64724 (JP 2012-64724 A). The vehicle is a hybrid vehicle that includes an engine and a motor, and the control unit is a device that controls driving electric power for a motor. In a front compartment, the control unit is fixed on a case of a drive system including the motor.

A cooler in which a liquid refrigerant is used is accommodated together with a large number of electrical components in a case of the control unit. A refrigerant pipe that is connected to the cooler extends through a wall of the case and extends to the outside of the case. The liquid refrigerant is supplied from the outside through the refrigerant pipe. The refrigerant that has absorbed heat from the electrical components is discharged to the outside of the case through another refrigerant pipe.

### SUMMARY

When a collision load, which is generated at the time of collision of the vehicle, is applied to the refrigerant pipe in the control unit described in JP 2012-64724 A, the refrigerant pipe may be pushed into the case, and thus, the cooler in the case may be damaged and the refrigerant may leak in the case. The leakage of the refrigerant in the case may cause the damage to the electrical components that are accommodated in the case.

An aspect of the disclosure relates to an electrical apparatus configured to be mounted in a vehicle. The electrical apparatus includes a case that accommodates an electrical component; a cooler accommodated in the case and configured to cool the electrical component with use of a liquid refrigerant; and a refrigerant pipe that extends through a wall of the case and is connected to the cooler. A notch is provided on an outer surface of the refrigerant pipe such that the notch is located outside the case.

In the electrical apparatus, when a collision load, which is generated at the time of a collision of the vehicle, is applied to the refrigerant pipe, the notch, which is located outside the case, is first broken, and the refrigerant can be discharged to the outside of the case from the notch. As a result, it is possible to prevent the refrigerant from leaking in the case. Therefore, it is possible to prevent damage to the electrical apparatus, which is caused by the leakage of the refrigerant, at the time of the collision of the vehicle.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is an explanatory view showing a schematic configuration of a vehicle that is seen from above;

FIG. 2 is an explanatory view showing the schematic configuration of the vehicle that is seen from the left;

FIG. 3 is a perspective view showing a detailed configuration of an electric power control unit in a first embodiment, the electric power control unit being mounted in the vehicle;

FIG. 4 is a sectional view showing the detailed configuration of the electric power control unit that is seen along arrows in FIG. 3;

FIG. 5 is a partial sectional view showing the detailed configuration of the electric power control unit that is seen along arrows in FIG. 3;

FIG. 6 is an explanatory view showing an example of a state where a pipe portion of the electric power control unit is broken;

FIG. 7 is a partial sectional view showing a detailed configuration of an electric power control unit in a second embodiment;

FIG. 8 is a sectional view showing a detailed configuration of a pipe portion that is seen along arrows in FIG. 7;

FIG. 9 is an explanatory view showing an example of a state where the pipe portion of the electric power control unit is broken; and

FIG. 10 is a sectional view showing the detailed configuration of the pipe portion that is seen along arrows in FIG. 9.

### DETAILED DESCRIPTION OF EMBODIMENTS

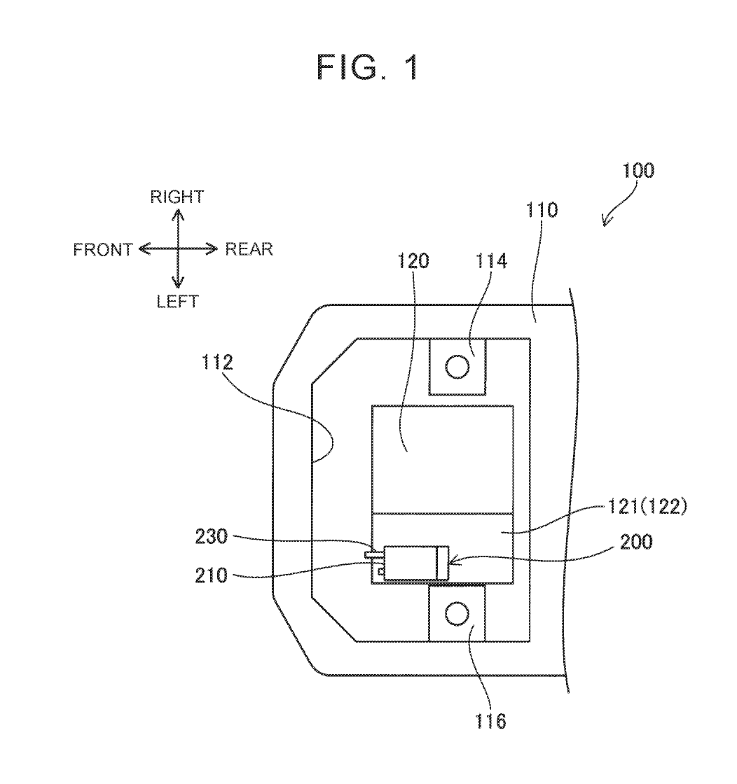

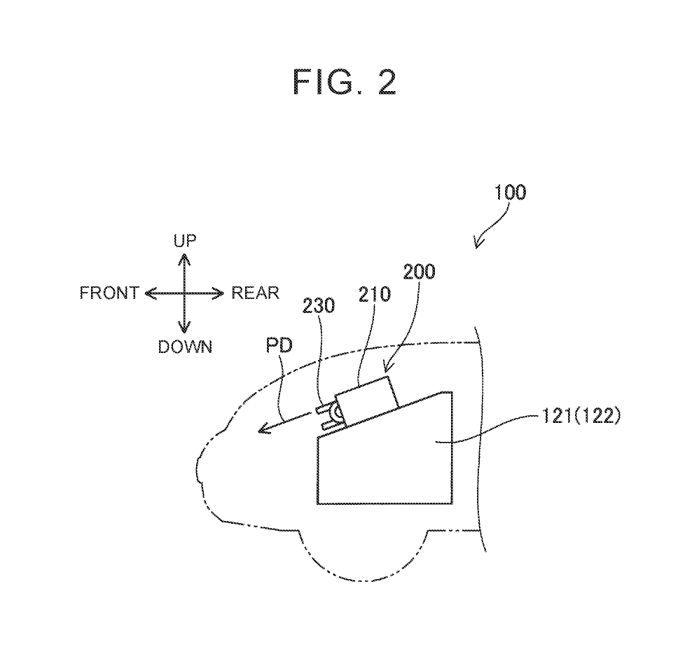

Hereinafter, a first embodiment of the disclosure will be described. FIG. 1 is an explanatory view showing a schematic configuration of a vehicle 100 that is seen from above. FIG. 2 is an explanatory view showing the schematic configuration of the vehicle 100 that is seen from the left. Each of FIG. 1 and FIG. 2 shows a front portion of the vehicle 100. In the vehicle 100, an electric motor generates at least part of power for driving drive wheels. The vehicle 100 is a hybrid vehicle that includes, as power sources, the electric motor and an engine. In the following description, the electric motor will be simply referred to as a motor. In a coordinate system in each of FIG. 1 and FIG. 2, each of “front”, “rear”, “right”, “left”, “up”, and “down” signifies a direction with respect to the vehicle 100. The same applies to the other drawings, which will be described below.

The vehicle 100 includes a vehicle body 110, an engine 120, a transaxle 121, and an electric power control unit 200. A motor 122 is accommodated in the transaxle 121. The engine 120 and the transaxle 121 are coupled to each other in a vehicle width direction. An output shaft of the engine 120 and an output shaft of the motor 122 are moved in conjunction with each other by a gear set that is provided in the transaxle 121. A power supply (not shown) for driving the motor 122 is mounted in a rear portion of the vehicle 100.

The electric power control unit 200 of the vehicle 100 is fixed on the transaxle 121. The electric power control unit 200 is fixed on the transaxle 121 in a state in which the electric power control unit 200 is inclined downward in a forward direction. The electric power control unit 200 controls driving electric power for the motor 122. The electric power control unit 200 is also referred to as a power control unit (PCU). The electric power control unit 200 includes a case 210 and a first external refrigerant pipe 230.

The case 210 accommodates an electrical component and a cooler that cools the electrical component. The first external refrigerant pipe 230 is fixed to an outer side of the case 210. The first external refrigerant pipe 230 extends obliquely downward toward the front side of the vehicle 100 from a front surface of the case 210. In the first external refrigerant pipe 230, a channel through which a refrigerant flows is formed. The first external refrigerant pipe 230 is connected to a refrigerant circulator (not shown) that circulates the refrigerant. The refrigerant flows from the outside of the electric power control unit 200 into the case 210 through the first external refrigerant pipe 230. A detailed configuration of the electric power control unit 200 will be described below.

The vehicle body 110 of the vehicle 100 forms a contour of the vehicle 100. The vehicle body 110 includes an engine compartment 112 provided in the front portion of the vehicle 100. In the engine compartment 112, the engine 120, the transaxle 121 (the motor 122), the electric power control unit 200, and the like are arranged. The vehicle body 110 includes mounts 114, 116. The mount 114 supports a suspension (not shown) for a right front wheel. The mount 116 supports a suspension (not shown) for a left front wheel.

The mount 114 is located at a right end in the engine compartment 112. The mount 116 is located at a left end in the engine compartment 112. The engine 120 and the transaxle 121 are located between the mount 114 and the mount 116, and protrude in a front-rear direction beyond the mounts 114, 116 (more specifically, the engine 120 and the transaxle 121 protrude forward beyond the mounts 114, 116, and protrude rearward beyond the mounts 114, 116).

The electric power control unit 200 is located on a left side of the engine 120 and is located on a right side of the mount 116. The electric power control unit 200 is provided between the engine 120 and the mount 116. The first external refrigerant pipe 230 of the electric power control unit 200 extends obliquely downward toward the front side of the vehicle 100 (in a direction of an arrow PD in FIG. 2) from the front surface of the case 210. The first external refrigerant pipe 230 projects toward the front side beyond the engine 120.

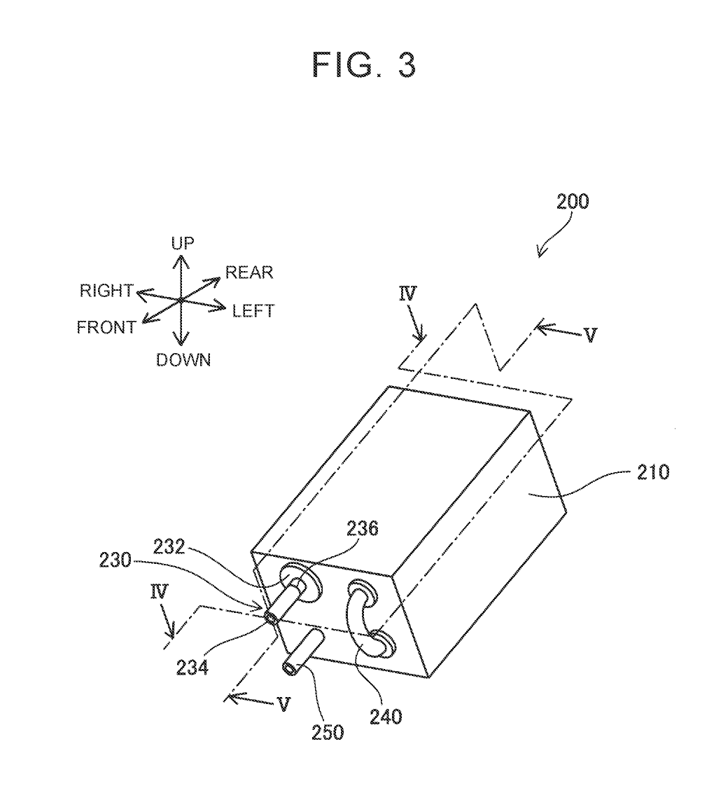

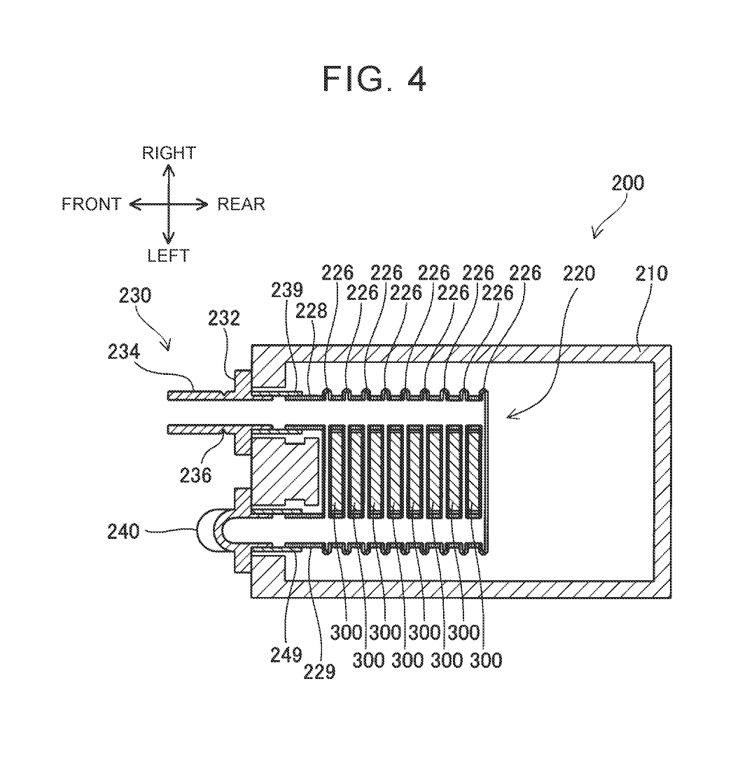

FIG. 3 is a perspective view showing the detailed configuration of the electric power control unit 200 that is mounted in the vehicle 100. FIG. 4 is a sectional view showing the detailed configuration of the electric power control unit 200 that is seen along arrows IV-IV in FIG. 3. In addition to the case 210 and the first external refrigerant pipe 230, the electric power control unit 200 includes a cooler 220, a second external refrigerant pipe 240, a third external refrigerant pipe 250, and a plurality of electrical components 300.

The first external refrigerant pipe 230 of the electric power control unit 200 guides the refrigerant into the case 210. The third external refrigerant pipe 250 of the electric power control unit 200 is used to discharge the refrigerant to the outside of the case 210 (in other words, the refrigerant is discharged to the outside of the case 210 through the third external refrigerant pipe 250). The third external refrigerant pipe 250 is located on a front side of the case 210. Similarly to the first external refrigerant pipe 230, the third external refrigerant pipe 250 extends obliquely downward toward the front side of the vehicle 100 from the front surface of the case 210.

In the electric power control unit 200, the case 210 thereof accommodates the plurality of electrical components 300 and the cooler 220. The electrical components 300 constitute a power module in which a plurality of power semiconductor elements (power devices) are enclosed. Each of the electrical components 300 generates heat when energized, and is cooled by the cooler 220.

The cooler 220 includes a plurality of cooling plates 226. The plurality of cooling plates 226 and the plurality of electrical components 300 are stacked alternately one by one. Each of the cooling plates 226 is hollow, and the refrigerant flows through the inside of the cooling plate 226. The cooling plates 226 adjacent to each other communicate with each other at two positions. In FIG. 4, a first internal refrigerant pipe 228 and a second internal refrigerant pipe 229 are connected to the cooling plate 226 at a left end. The first internal refrigerant pipe 228 is connected to the first external refrigerant pipe 230 via a gasket 239. The second internal refrigerant pipe 229 is connected to the second external refrigerant pipe 240 via a gasket 249. Each of the gaskets 239, 249 is made of a resin. The refrigerant is supplied to the cooler 220 via the first external refrigerant pipe 230 and the first internal refrigerant pipe 228. The refrigerant that has been supplied to the cooler 220 is distributed to the plurality of cooling plates 226. While flowing through each of the cooling plates 226, the refrigerant absorbs the heat of the electrical component(s) 300 adjacent to the cooling plate 226. The refrigerant that has absorbed the heat is delivered to another cooler via the second internal refrigerant pipe 229 and the second external refrigerant pipe 240. The other cooler is accommodated in a lower portion of the case 210. The refrigerant that has flowed through the other cooler is discharged to the outside of the case 210 via the third external refrigerant pipe 250. As described above, the refrigerant is circulated between the refrigerant circulator, which is not shown, and the electric power control unit 200.

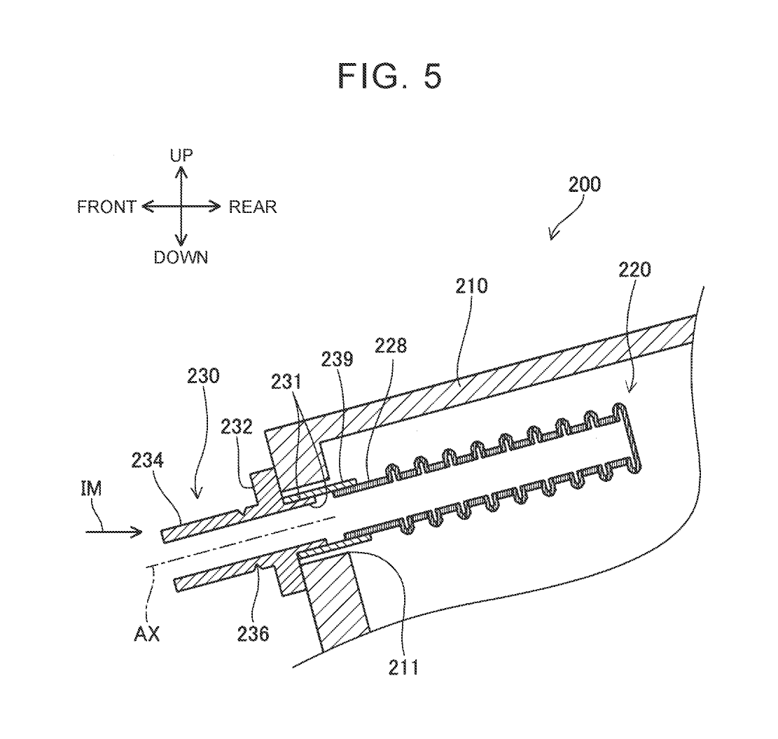

FIG. 5 is a partial sectional view showing the detailed configuration of the electric power control unit 200 that is seen along arrows V-V in FIG. 3. In the electric power control unit 200, a body 234 of the first external refrigerant pipe 230 has an axis AX that extends in an obliquely downward direction toward the front side of the vehicle 100. A distal end 231 of the first external refrigerant pipe 230 is inserted in a through-hole 211 provided in the case 210 (i.e., the through-hole 211 provided in a wall (an outer wall) of the case 210, the wall defining an external shape of the case 210), from the outside of the case 210. In the through-hole 211, the distal end 231 of the first external refrigerant pipe 230 is connected to the gasket 239. The distal end 231 of the first external refrigerant pipe 230 is connected to the first internal refrigerant pipe 228 via the gasket 239. A refrigerant pipe that includes the first external refrigerant pipe 230 and the first internal refrigerant pipe 228 extends through the through-hole 211 (in other words, the refrigerant pipe that includes the first external refrigerant pipe 230 and the first internal refrigerant pipe 228 extends through the case 210, more specifically, extends through the wall of the case 210). Similarly to the first external refrigerant pipe 230, the first internal refrigerant pipe 228 is inclined such that an axis of the first internal refrigerant pipe 228 extends obliquely downward toward the front side of the vehicle 100. That is, the refrigerant pipe that includes the first external refrigerant pipe 230 and the first internal refrigerant pipe 228 extends obliquely downward toward the front side of the vehicle 100. The cooler 220 is also inclined such that a refrigerant channel therein extends obliquely downward toward the front side of the vehicle 100.

A flange 232 is provided at a distal end of a body 234 of the first external refrigerant pipe 230. The flange 232 contacts a side surface of the case 210. Although not shown, the flange 232 is fixed to the case 210 by a bolt. On an opposite side of the flange 232 from the case 210, a notch 236 is provided on an outer surface of the body 234 of the first external refrigerant pipe 230.

The notch 236 of the first external refrigerant pipe 230 is formed on the outer surface of the body 234. In the body 234, at a position near the flange 232, the notch 236 extends linearly along the entire outer periphery of the body 234. In other words, the notch 236 is a groove that is located outside the case 210 and extends along the entire outer periphery of the first external refrigerant pipe 230.

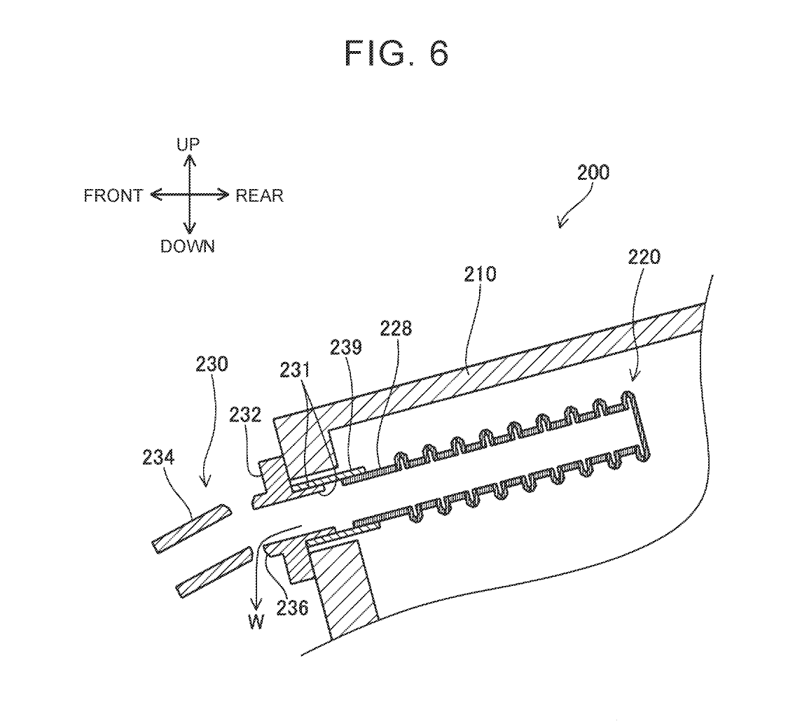

FIG. 6 is an explanatory view showing an example of a state where the body 234 of the first external refrigerant pipe 230 is broken. The state in FIG. 6 is a state where a collision load IM is applied to the electric power control unit 200 in FIG. 5 from the front side and the body 234 is thereby broken at the notch 236. The body 234 is thinner at the notch 236 extending along the entire circumference (i.e., the entire outer periphery) of the body 234 than at other portions (i.e., at the rest of the body 234), that is, the thin portion of the body 234 extends along the entire circumference (i.e., the entire outer periphery) of the body 234. In other words, the body 234 is thinnest at the notch 236. Accordingly, when the collision load IM is applied to the body 234 from the front side, the body 234 of the first external refrigerant pipe 230 can be broken at the notch 236 by concentrating stress on the notch 236. At the time, due to a gravitational force, a refrigerant W that remains in the cooler 220 flows out of the case 210 of the electric power control unit 200 through the opened notch 236 (i.e., the broken notch 236) of the body 234.

According to the embodiment that has been described so far, when the collision load IM, which is generated at the time of a collision of the vehicle 100, is applied to the first external refrigerant pipe 230, the body 234 is opened preferentially at the notch 236. Thus, the refrigerant W can be discharged from the cooler 220 to the outside of the case 210 through the opened notch 236 of the first external refrigerant pipe 230. Thus, it is possible to prevent the refrigerant W from leaking in the case 210. As a result, it is possible to prevent damage to the electrical components 300, which is caused by the leakage of the refrigerant W, at the time of the collision of the vehicle 100.

In addition, in the vehicle 100 that includes the electric power control unit 200, the body 234 of the first external refrigerant pipe 230 projects in a direction of gravity (more specifically, obliquely downward) from the case 210. The cooler 220 is located above the notch 236. Thus, when the collision load IM, which is generated at the time of the collision of the vehicle 100, is applied to the first external refrigerant pipe 230, the refrigerant W is guided from the cooler 220 to the body 234 by the gravitational force. Thus, the refrigerant W can be further effectively discharged from the cooler 220 to the outside of the case 210 through the notch 236.

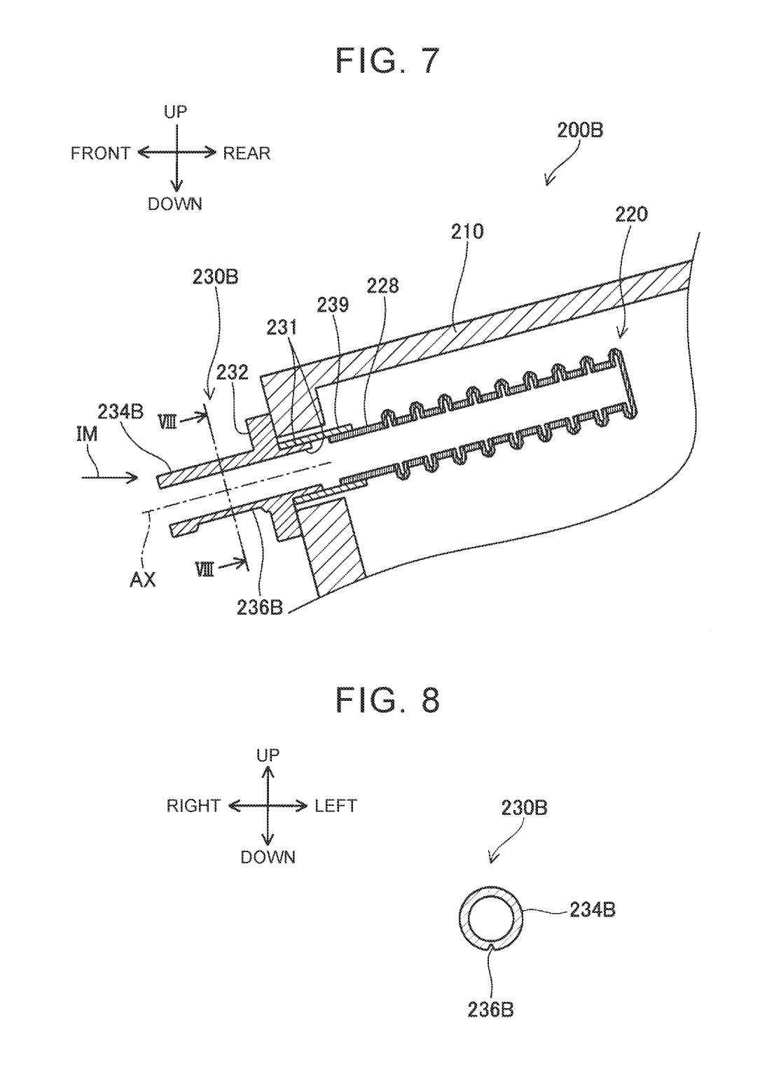

Hereinafter, a second embodiment of the disclosure will be described. FIG. 7 is a partial sectional view showing a detailed configuration of an electric power control unit 200B in the second embodiment. FIG. 8 is a sectional view showing a detailed configuration of a body 234B of a first external refrigerant pipe 230B that is seen along arrows VIII-VIII in FIG. 7. The electric power control unit 200B in the second embodiment is the same as the electric power control unit 200 in the first embodiment except that the electric power control unit 200B includes the first external refrigerant pipe 230B instead of the above-described first external refrigerant pipe 230. The first external refrigerant pipe 230B in the second embodiment is the same as the first external refrigerant pipe 230 in the first embodiment except that the first external refrigerant pipe 230B includes the body 234B provided with a notch 236B instead of the body 234 provided with the notch 236.

The body 234B of the first external refrigerant pipe 230B is a cylindrical portion that projects to the outside of the case 210 from the flange 232. The axis AX of the body 234B extends obliquely downward toward the front side of the vehicle 100.

The notch 236B of the first external refrigerant pipe 230B is formed on an outer surface of the body 234B. On the outer surface of the body 234B, the notch 236B is formed in a portion that faces downward. The notch 236B extends linearly in a projected direction of the body 234B. In other words, the notch 236B extends linearly along the axis AX of the body 234B of the first external refrigerant pipe 230B.

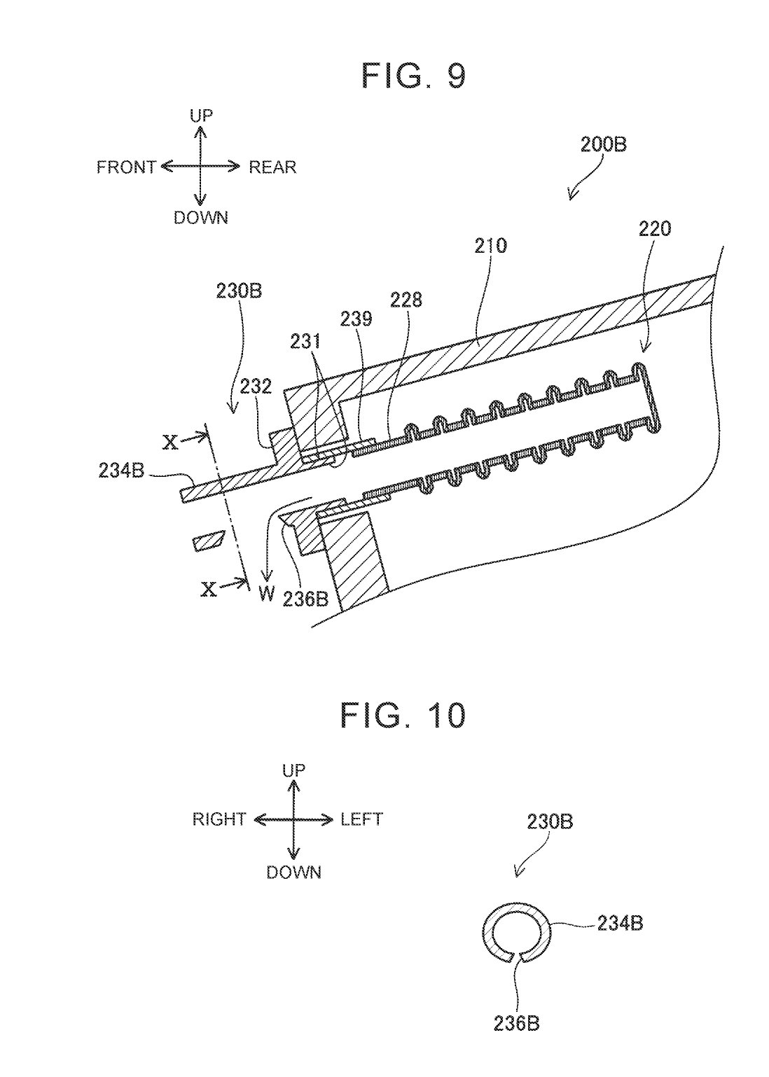

FIG. 9 is an explanatory view showing an example of a state where the body 234B of the first external refrigerant pipe 230B in the electric power control unit 200B is broken. FIG. 10 is a sectional view showing a detailed configuration of the body 234B that is seen along arrows X-X in FIG. 9. A state in each of FIG. 9 and FIG. 10 is a state where the collision load IM is applied to the electric power control unit 200B in FIG. 7 from the front side and the body 234B is thereby broken at the notch 236B. The body 234B is thinner at the notch 236B extending linearly along the axis AX than at other portions (i.e., at the rest of the body 234B), that is, the thin portion of the body 234B extends linearly along the axis AX. In other words, the body 234B is thinnest at the notch 236B. Accordingly, when the collision load IM is applied to the body 234B from the front side, the body 234B can be opened at the notch 236B by concentrating the stress on the notch 236B. At the time, due to the gravitational force, the refrigerant W that remains in the cooler 220 flows out of the case 210 through the opened notch 236B of the body 234B.

According to the second embodiment that has been described so far, when the collision load IM, which is generated at the time of the collision of the vehicle 100, is applied to the first external refrigerant pipe 230B, the body 234B is opened preferentially at the notch 236B. Thus, the refrigerant W can be discharged from the cooler 220 to the outside of the case 210 through the opened notch 236B. Thus, it is possible to prevent the refrigerant W from leaking in the case 210. As a result, it is possible to prevent the damage to the electrical components 300, which is caused by the leakage of the refrigerant W, at the time of the collision of the vehicle 100.

In addition, in the vehicle 100 that includes the electric power control unit 200B, the notch 236B is formed in the portion of the outer surface of the first external refrigerant pipe 230B, the portion facing the direction of gravity (i.e., facing downward). The notch 236B extends linearly in the direction in which the body 234B projects. That is, the notch 236B is provided on the lower surface of the first external refrigerant pipe 230B, and extends along the axial direction of the first external refrigerant pipe 230B. Thus, when the collision load IM, which is generated at the time of the collision of the vehicle 100, is applied to the first external refrigerant pipe 230B, the portion of the body 234B, which faces the direction of gravity (i.e., extends obliquely downward toward the front side), is preferentially opened at the notch 236B. Thus, the refrigerant W can be further effectively discharged from the cooler 220 to the outside of the case 210 through the opened notch 236B.

Points to be noted with regard to the technique in the embodiments will be described. The first external refrigerant pipe 230 (230B) and the first internal refrigerant pipe 228 (228B) are connected to each other and correspond to an example of the “refrigerant pipe”. The second internal refrigerant pipe 229 and the second external refrigerant pipe 240 are connected to each other and constitute another refrigerant pipe. The other refrigerant pipe may have the same configurations as the configurations of the first external refrigerant pipe 230 (230B) and the first internal refrigerant pipe 228 (228B). The same applies to the third external refrigerant pipe 250. The technique disclosed in the present specification can be also applied to an electrical apparatus other than the electric power control unit.

The embodiments have been described so far in detail. However, they are merely illustrative and thus do not limit the scope of the disclosure. The scope of the disclosure includes various modifications and changes that are made to the above-described embodiments. In addition, the technical elements that are described in the present specification and the drawings demonstrate technical utility when used singly or in various combinations, and thus are not limited to the combinations described in the above-described embodiments. Furthermore, the techniques that are described in the present specification and the drawings achieve a plurality of objects simultaneously, and technical utility is provided by achieving at least one of the plurality of objects.

What is claimed is:

1. An electrical apparatus configured to be mounted in a vehicle, the electrical apparatus comprising:
a case that accommodates an electrical component;
a cooler accommodated in the case and configured to cool the electrical component with use of a liquid refrigerant; and
a refrigerant pipe that extends through a wall of the case and is connected to the cooler, wherein
a notch is provided on an outer surface of the refrigerant pipe such that the notch is located outside the case.

2. The electrical apparatus according to claim 1, wherein the notch extends along an entire outer periphery of the refrigerant pipe.

3. The electrical apparatus according to claim 1, wherein in a state where the electrical apparatus is mounted in the vehicle, the notch is provided on a lower surface of the refrigerant pipe and extends along an axial direction of the refrigerant pipe.

4. The electrical apparatus according to claim 1, wherein:
the electrical apparatus is mounted in a front compartment of the vehicle; and
in a state where the electrical apparatus is mounted in the vehicle, the refrigerant pipe extends obliquely downward toward a front side of the vehicle from the case.
